(19) United States
(12) Patent Application Publication
(10) Pub. No.: US 2025/0293182 A1
(43) Pub. Date: Sep. 18, 2025

(54) COMPACT DEVICE FOR IMPROVED HIGH-SPEED SIGNAL INTEGRITY

(71) Applicant: QUALCOMM Incorporated, San Diego, CA (US)

(72) Inventor: Pedro WILSON DE ABREU FARIAS NETO, Crosshaven (IE)

(21) Appl. No.: 18/604,273

(22) Filed: Mar. 13, 2024

(51) Int. Cl. H01L 23/64; H01F 27/28; H01L 23/60

(52) U.S. Cl. CPC H01L 23/645; H01F 27/2871; H01L 23/60

(57) ABSTRACT

A chip includes a pad, and a T-coil circuit having a first terminal, a second terminal, and a third terminal, wherein the first terminal of the T-coil circuit is coupled to the pad. The T-coil circuit includes a first inductor coupled between the first terminal and the third terminal, and a second inductor coupled between the third terminal and the second terminal, wherein the first inductor and the second inductor are inductively coupled to one another. The chip also includes a receive circuit coupled to the second terminal of the T-coil circuit, a termination resistor, a third inductor coupled between the second terminal of the T-coil circuit and the termination resistor, and a bridge capacitor coupled between the pad and the termination resistor.

### BACKGROUND

### Field

Aspects of the present disclosure relate generally to a T-coil circuit, and more particularly, to a boosted T-coil circuit.

### Background

A chip may include a receive circuit and a pad coupled to the receive circuit. The pad may be coupled to an external device via a channel for receiving a high-speed signal (e.g., a high-speed data signal) from the external device. The receive circuit receives the high-speed signal from the pad and processes the high-speed signal (e.g., to recover data bits from the high-speed signal). Since the pad provides an interface between the external world and internal circuitry (e.g., the receive circuit) of the chip, an electrostatic discharge (ESD) protection circuit is typically provided at the pad to protect the internal circuitry from damage due to ESD.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a pad, and a T-coil circuit having a first terminal, a second terminal, and a third terminal, wherein the first terminal of the T-coil circuit is coupled to the pad. The T-coil circuit includes a first inductor coupled between the first terminal and the third terminal, and a second inductor coupled between the third terminal and the second terminal, wherein the first inductor and the second inductor are inductively coupled to one another. The chip also includes a receive circuit coupled to the second terminal of the T-coil circuit, a termination resistor, a third inductor coupled between the second terminal of the T-coil circuit and the termination resistor, and a bridge capacitor coupled between the pad and the termination resistor.

A second aspect relates to a chip. The chip includes a pad, an electrostatic discharge (ESD) protection circuit, a receive circuit, a first inductor coupled between the pad and the ESD protection circuit, and a second inductor coupled between the ESD protection circuit and the receive circuit, wherein the first inductor and the second inductor are inductively coupled to one another. The chip also includes a termination resistor, a third inductor coupled between the receive circuit and the termination resistor, and a bridge capacitor coupled between the pad and the termination resistor.

### BRIEF DESCRIPTION OF THE DRAWINGS

FIG. 1A shows an example of a chip including a pad, a receive circuit, and an electrostatic discharge (ESD) protection circuit according to certain aspects of the present disclosure.

FIG. 1B shows an exemplary implementation of the receive circuit according to certain aspects of the present disclosure.

FIG. 2 shows an example of the chip further including a T-coil circuit and a bridge capacitor according to certain aspects of the present disclosure.

FIG. 3 shows an equivalent circuit of the T-coil circuit according to certain aspects of the present disclosure.

FIG. 4 shows termination paths to a termination resistor through the T-coil circuit and the bridge capacitor according to certain aspects of the present disclosure.

FIG. 5 shows an example of the chip further including a boost inductor coupled to the T-coil circuit according to certain aspects of the present disclosure.

FIG. 6 shows an equivalent circuit of the T-coil circuit and the boost inductor according to certain aspects of the present disclosure.

FIG. 7 shows termination paths to a termination resistor through the T-coil circuit, the boost inductor, and the bridge capacitor according to certain aspects of the present disclosure.

FIG. 8 shows an exemplary high-frequency equivalent circuit of the T-coil circuit and the boost inductor according to certain aspects of the present disclosure.

FIG. 9 shows an exemplary layout of the T-coil circuit and the boost inductor according to certain aspects of the present disclosure.

FIG. 10A shows an exemplary layout of a first inductor of the T-coil circuit according to certain aspects of the present disclosure.

FIG. 10B shows an exemplary layout of a second inductor of the T-coil circuit according to certain aspects of the present disclosure.

FIG. 10C shows an exemplary layout of the T-coil with the first inductor stacked on top of the second inductor according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

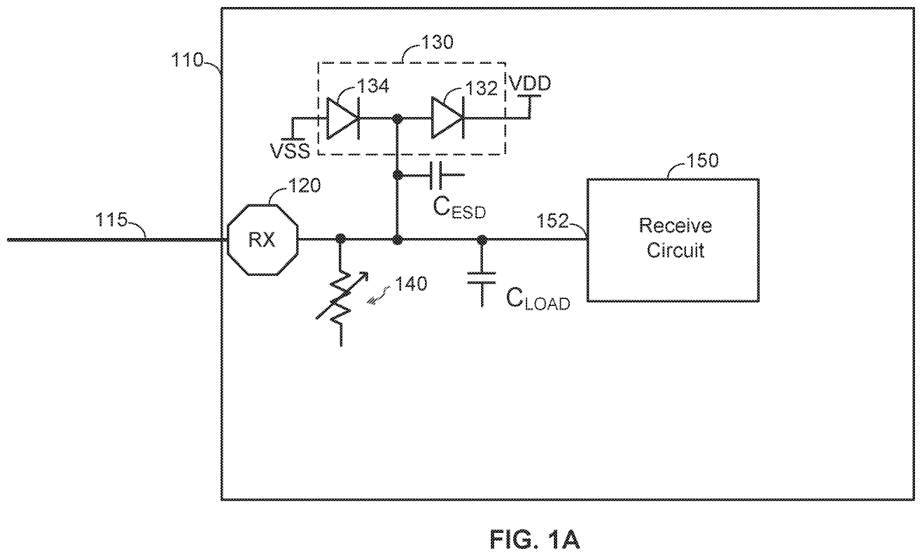

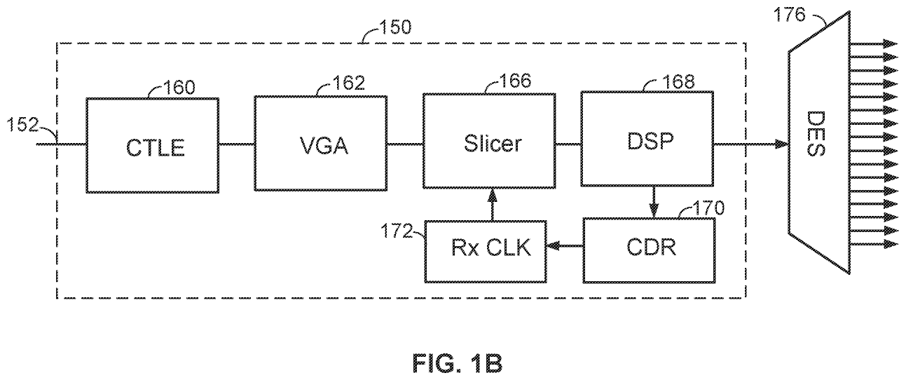

FIG. 1A shows an example of a chip 110 (i.e., a die) including a pad 120 and a receive circuit 150. The input 152 of the receive circuit 150 is coupled to the pad 120 for receiving a high-speed signal from an external device (not shown in FIG. 1A) via a channel 115. The high-speed signal may be a high-speed data signal (e.g., on the order of several gigabits per second (Gbps) to tens of Gbps). The high-speed signal may carry data in a sequence of symbols where each symbol carries one or more bits. For example, the external device may generate the symbols using non-return-to-zero (NRZ) modulation where each symbol is transmitted at one of two voltage levels to represent the bit value of one bit. In another example, the external device may generate symbols using pulse amplitude modulation 4-level (PAM-4) where each symbol is transmitted at one of four voltage levels to represent the bit values of two binary bits. However, it is to be appreciated that the present disclosure is not limited to these examples, and that other types of modulation schemes may be employed in other implementations.

In certain aspects, the chip 110 is packaged in a package (not shown), which may be mounted on a printed circuit board (PCB). In this example, the pad 120 may be coupled to one or more metal traces on the PCB by a bump (e.g., a solder bump) and metal routing in the package. In this example, the channel 115 may include the one or more metal traces, the metal routing in the package, and the bump. However, it is to be appreciated that the channel 115 is not limited to this example.

In this example, the receive circuit 150 receives the high-speed signal from the channel 115 through the pad 120. The receive circuit 150 then processes the received high-speed signal (e.g., to recover the data bits from the high-speed signal). FIG. 1B shows an exemplary implementation of the receive circuit 150. In this example, the receive circuit 150 may include a continuous time linear equalizer (CTLE) 160 to compensate for high frequency attenuation in the channel 115, a variable gain amplifier (VGA) 162, a slicer 166 to convert the high-speed signal into a digital signal (e.g., make bit decisions), and a digital signal processor (DSP) 168 to process the output of the slicer 166 in the digital domain. For example, the DSP 168 may perform decision feedback equalization (DFE) to compensate for intersymbol interference (ISI), and/or feed-forward equalization (FFE). In this example, the receive circuit 150 also includes a clock data recovery (CDR) circuit 170 for extracting timing information from the output of the slicer 166, and a clock generator 172 for generating a receive clock signal based on the extracted timing information. The receive clock signal is input to the slicer 166 to time sampling of the high-speed signal by the slicer 166.

It is to be appreciated that the receive circuit 150 is not limited the example shown in FIG. 1B. For example, the receive circuit 150 may include one or more additional components not shown in FIG. 1B and/or one or more of the components shown in the example in FIG. 1B may be omitted in some implementations. For serializer/deserializer (SerDes) communication across the channel 115, the chip 110 may include a deserializer 176 coupled to the receive circuit 150 to convert the bits from the receive circuit 150 into parallel bit streams.

Returning to FIG. 1A, the chip 110 includes a termination resistor 140 to provide impedance matching with the channel 115 (e.g., 50 Ohm). The termination resistor 140 may be coupled between the pad 120 and a ground. As used herein, a “ground” may be a DC ground or an AC ground.

In the example shown in FIG. 1A, the chip 110 also includes an electrostatic discharge (ESD) protection circuit 130 coupled to the pad 120 to protect internal circuitry (e.g., receive circuit 150) of the chip 110 from damage due to an ESD event. An ESD event may occur, for example, when a charged object makes contact with the pad 120 (e.g., during handling of the chip 110). An ESD event may also occur, for example, when the chip 110 acquires charge and then discharges to an object making contact with the pad 120. If left unprotected against ESD, an ESD event may damage or destroy the gate oxide, metallization, and/or PN junction of an electronic component on the chip 110. Damage caused by ESD events may reduce manufacturing yields and/or lead to operational failures of electronic components.

In the example shown in FIG. 1A, the ESD protection circuit 130 includes a first diode 132 coupled between the pad 120 and a VDD bus, and a second diode 134 coupled between a VSS bus and the pad 120. In this example, the first diode 132 provides an ESD current path from the pad 120 to the VDD bus and the second diode 134 provides an ESD current path from the VSS bus to the pad 120 depending on the direction of the ESD current. It is to be appreciated that the chip 110 may include one or more additional components to provide ESD protection (e.g., an ESD clamp coupled between the VDD bus and the VSS bus).

While the diodes 132 and 134 of the ESD protection circuit 130 provide ESD protection, the diodes 132 and 134 have a large load capacitance, which reduces bandwidth and degrades impedance matching. In FIG. 1A, the load capacitance of the diodes 132 and 134 (also referred to as ESD load capacitance) is modeled by the capacitor C_{ESD}, and the load capacitance of the receive circuit 150 (which may be much smaller) is modeled by the capacitor C_{LOAD}. The bandwidth reduction caused by the load capacitance of the ESD protection circuit 130 may prevent the receive circuit 150 from achieving high data rates for high-speed applications. In addition, the impedance matching degradation increases return loss which degrades signal integrity. The sizes of the diodes 132 and 134 may be reduced to reduce the load capacitance of the diodes 132 and 134. However, this reduces the amount of ESD protection provided by the diodes 132 and 134.

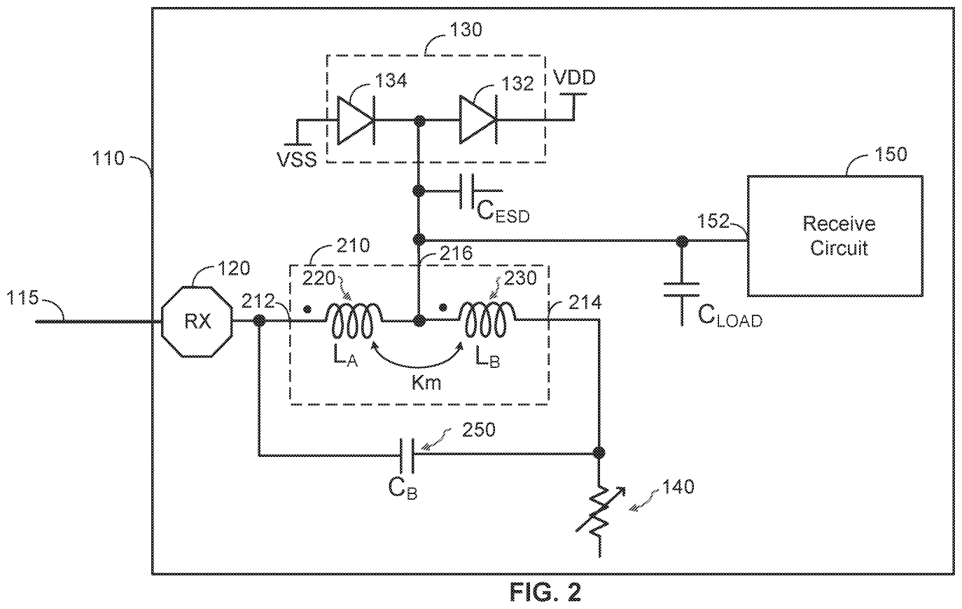

To address the negative effects of ESD load capacitance on bandwidth and impedance matching, a T-coil circuit may be added to provide bandwidth extension and good impedance matching over a wide frequency range. In this regard, FIG. 2 shows an example in which the chip 110 includes a T-coil circuit 210 and a bridge capacitor 250 according to certain aspects. The T-coil circuit 210 may also be referred to simply as a T-coil, referred to as a T-coil network, or referred to by another term.

The T-coil circuit 210 has a first terminal 212, a second terminal 214, and a third terminal 216. The first terminal 212 is coupled to the pad 120 and the second terminal 214 coupled to the termination resistor 140. The ESD protection circuit 130 and the receive circuit 150 are coupled to the third terminal 216 of the T-coil circuit 210. The bridge capacitor 250 is coupled between the pad 120 and the termination resistor 140.

The T-coil circuit 210 includes a first inductor 220 coupled between the first terminal 212 and the third terminal 216 and a second inductor 230 coupled between the third terminal 216 and the second terminal 214. The first inductor 220 and the second inductor 230 are inductively (i.e., magnetically) coupled with one another (i.e., mutually coupled) with a coupling factor (i.e., coupling coefficient) of Km. The dot next to each of the inductors 220 and 230 indicates the direction of the inductor winding. In this example, the inductors 220 and 230 are wound to achieve a negative mutual inductance of −M where M is the mutual inductance given by:

$$M = Km \sqrt{{L}_{A} {L}_{B}} \qquad ( Eq . 1 )$$

where Km is the coupling factor between the inductors 220 and 230, L_{A} is the inductance of the first inductor 220, and L_{B} is the inductance of the second inductor 230. The coupling factor Km may be between 0.3 and 0.7, but is not limited to this example.

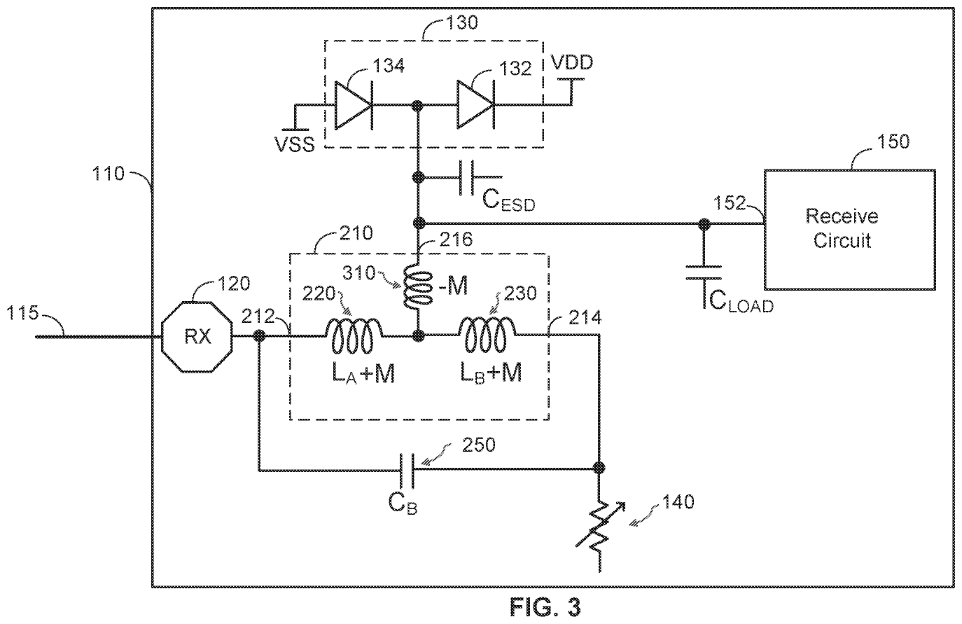

FIG. 3 shows an equivalent circuit in which the negative mutual inductance is modeled as an inductor 310 with a negative inductance of −M. It is to be appreciated that the inductor 310 shown in FIG. 3 models the negative mutual inductance of the inductors 220 and 230 shown in FIG. 2 and is not an actual physical inductor on the chip 110. In the equivalent circuit shown in FIG. 3, the first inductor 220 has an inductance of L_{A}+M and second inductor 230 has an inductance of L_{B}+M.

In the example shown in FIG. 3, the negative mutual inductance-M is coupled in series with the load capacitance of the diodes 132 and 134. The negative mutual inductance boosts the current flow to the load capacitance of the diodes 132 and 134, which charges the load capacitance faster and hence extends the bandwidth. Thus, the T-coil circuit 210 extends the bandwidth, which allows the receive circuit 150 to achieve higher data rates. The T-coil circuit 210 extends the bandwidth by approximately 2.7 compared with the case of no T-coil circuit shown in FIG. 1A.

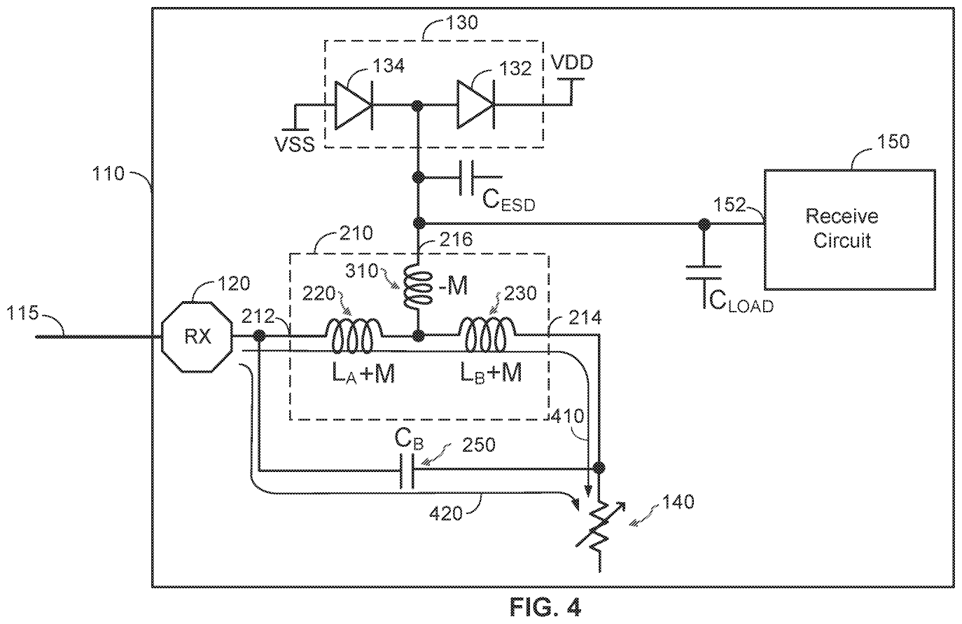

The T-coil circuit 210 and the bridge capacitor 250 provide good impedance matching over a wide frequency range. Referring to FIG. 4, at low frequencies, the inductors 220 and 230 act as shorts that provide a termination path 410 from the pad 120 to the termination resistor 140, which provides impedance matching at low frequencies. At high frequencies, the bridge capacitor 250 acts as a short that provides a termination path 420 from the pad 120 to the termination resistor 140, which provides impedance matching at high frequencies. In addition, the negative mutual inductance-M hides the ESD load capacitance from the termination paths 410 and 420 by counterbalancing the impedance of the ESD load capacitance. The good impedance matching reduces return loss and improves signal integrity.

The T-coil circuit 210 provides a bandwidth extension of approximately 2.7 times (i.e., 2.7×) over the case of no T-coil. However, this bandwidth extension may not be enough to achieve a target data rate as data rates continue to increase. Accordingly, additional bandwidth extension is desirable.

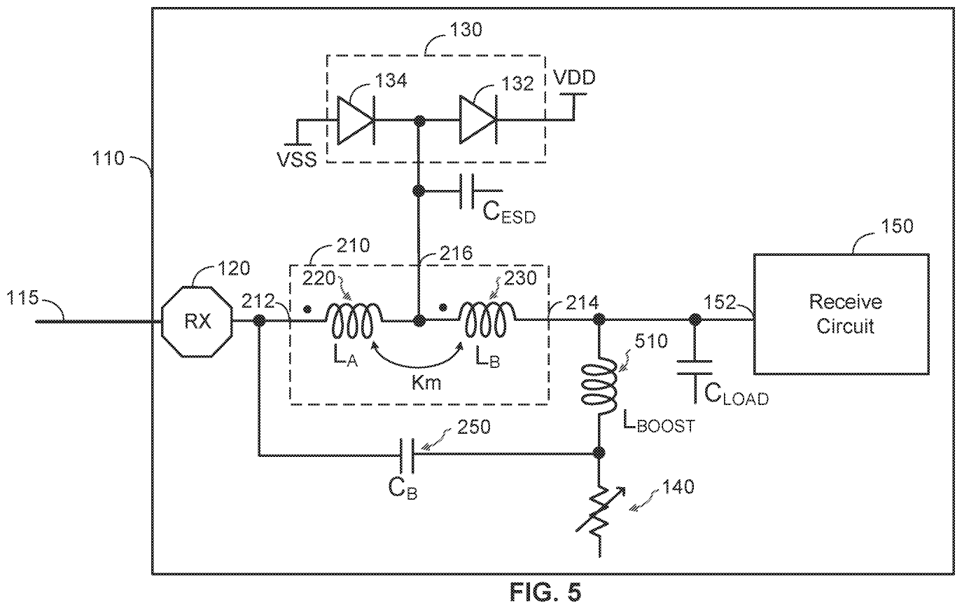

FIG. 5 shows an example in which the chip 110 further includes a boost inductor 510 according to certain aspects. As discussed further below, the boost inductor 510 provides additional bandwidth extension using inductive peaking. In this example, the boost inductor 510 is coupled between the second terminal 214 of the T-coil circuit 210 and the termination resistor 140, and the bridge capacitor 250 is coupled between the pad 120 and the termination resistor 140. The boost inductor 510 may also be referred to as a third inductor. The termination resistor 140 may be coupled between the bridge capacitor 250 and a ground.

In this example, the ESD protection circuit 130 is coupled to the third terminal 216 of the T-coil circuit 210, and the input 152 of the receive circuit 150 is coupled to the second terminal 214 of the T-coil circuit 210 instead of the third terminal 216. More particularly, the ESD protection circuit 130 is coupled to the center tap of the T-coil circuit 210 (i.e., the node between the inductors 220 and 230), and the input 152 of the receive circuit 150 is coupled to the node between the second inductor 230 and the boost inductor 510. Thus, in this example, the load capacitance of the receive circuit 150 (modeled by the capacitor C_{LOAD} in FIG. 5) is separated from the ESD load capacitance of the ESD protection circuit 130 (modeled by the capacitor C_{ESD} in FIG. 5). Also, in this example, the load capacitance of the receive circuit 150 is separated from the termination resistor 140 by the boost inductor 510.

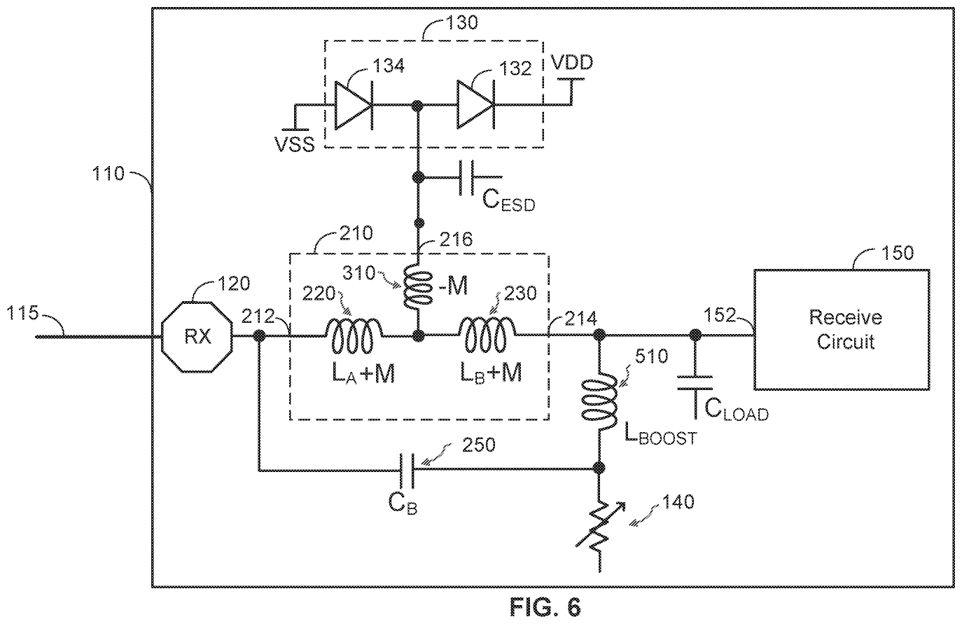

FIG. 6 shows an equivalent circuit of the T-coil circuit 210 in which the negative mutual inductance of the inductors 220 and 230 is modeled as the inductor 310 with the negative inductance of −M. In this example, the ESD load capacitance is separated from the load capacitance of the receive circuit 150 in which the negative mutual inductance −M hides the ESD load capacitance from the signal path of the receive circuit 150 by counterbalancing the impedance of the ESD load capacitance. Due to the separation between the ESD load capacitance and the load capacitance of the receive circuit 150, more bandwidth extension is applied to the load capacitance of the receive circuit 150 (which can be much smaller than the ESD load capacitance), as discussed further below.

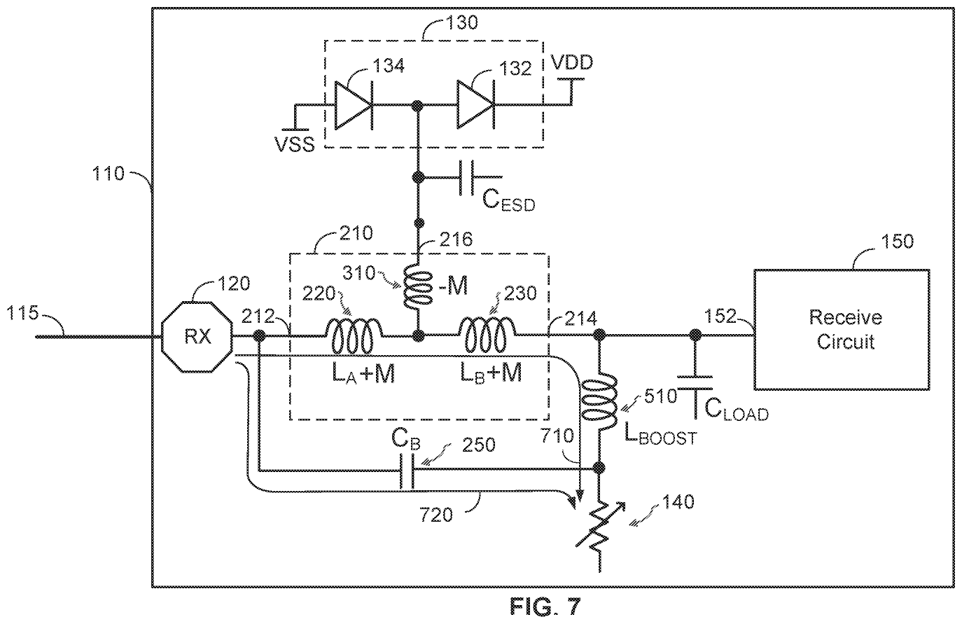

In this example, the T-coil circuit 210, the bridge capacitor 250, and the boost inductor 510 provide good impedance matching over a wide frequency range. Referring to FIG. 7, at low frequencies, the inductors 220 and 230 of the T-coil circuit 210 and the boost inductor 510 act as shorts that provide a termination path 710 from the pad 120 to the termination resistor 140, which provides impedance matching at low frequencies. At high frequencies, the bridge capacitor 250 acts as a short that provides a termination path 720 from the pad 120 to the termination resistor 140, which provides impedance matching at high frequencies. The good impedance matching reduces return loss and improves signal integrity.

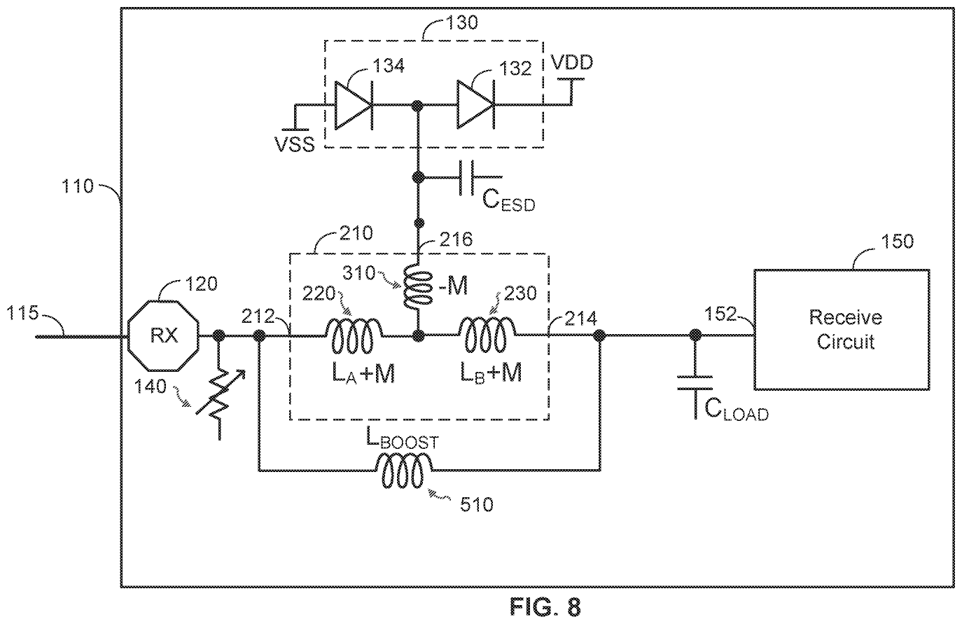

As discussed above, the boost inductor 510 provides additional bandwidth extension using inductive peaking. In this regard, FIG. 8 shows a high-frequency equivalent circuit in which the bridge capacitor 250 acts as a short (i.e., the bridge capacitor 250 is shorted). As shown in FIG. 8, at high frequencies, the boost inductor 510 is coupled between the pad 120 and the load capacitance of the receive circuit 150. In this example, the boost inductor 510 provides series inductive peaking which provides additional bandwidth extension.

In this example, the boost inductor 510 sees the load capacitance (i.e., C_{LOAD}) of the receive circuit 150, which is separated from the ESD load capacitance and may be much smaller than the ESD load capacitance. This reduces the capacitance seen by the boost inductor 510 which helps the inductive peaking achieve a higher effective bandwidth extension compared with the case where the ESD load capacitance and the load capacitance of the receive circuit 150 are not separated.

The boost inductor 510 may increase the bandwidth extension from 2.7× for the case of the T-coil circuit 210 without the inductive peaking to 4.6× or more. However, it is to be appreciated that the present disclosure is not limited to this example.

An inductance value for the boost inductor 510 to achieve a target bandwidth may be determined, for example, using a computer simulation or performing tests on a test circuit. For example, the bandwidth at the receive circuit 150 may be simulated or measured for different inductive values of the boost inductor 510 with the inductances of the inductors 220 and 230 held at fixed values. In this example, the inductor value of the boost inductor 510 achieving the target bandwidth may be chosen.

Although aspects of the present disclosure are discussed above using the example of the ESD protection circuit 130, it is to be appreciated that the present disclosure is not limited to this example. For example, the present disclosure may be used to provide bandwidth extension and improve impedance matching for other cases in which a circuit with a large load capacitance may be present at the interface. In these cases, the circuit may be coupled to the third terminal 216 of the T-coil circuit 210. Also, in these cases, the ESD protection circuit 130 may be omitted or the ESD protection circuit 130 may also be present in which case both the ESD protection circuit 130 and the circuit may be coupled to the third terminal 216 of the T-coil circuit 210.

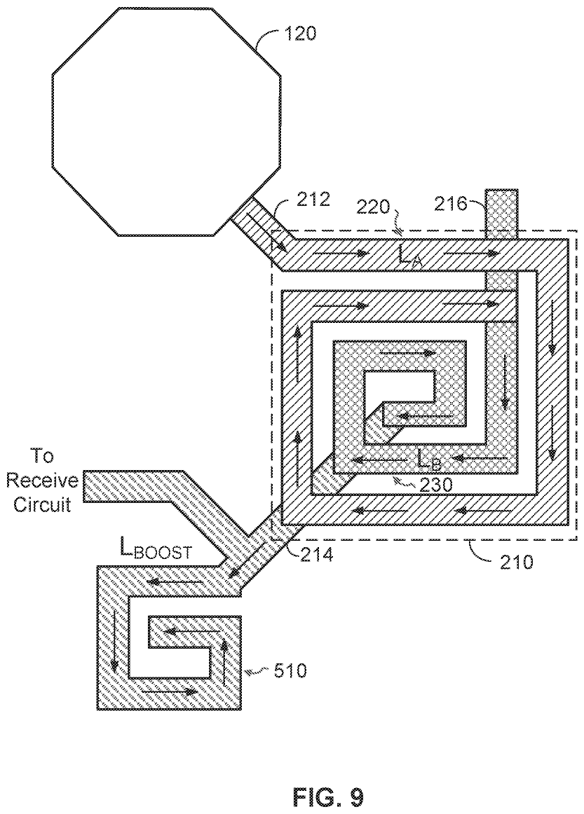

FIG. 9 shows a top view of an exemplary layout of the first inductor 220, the second inductor 230, and the boost inductor 510. In this example, each of the inductors 220, 230, and 510 is implemented with a respective planar inductor integrated on the chip 110. However, it is to be appreciated that the inductors 220, 230, and 510 are not limited to planar inductors.

The inductors 220, 230, and 510 may be formed from the same metal layer on the chip 110 (e.g., using lithographic and etching processes) or formed from different metal layers on the chip 110 (e.g., using lithographic and etching processes). For the example where the inductors 220, 230, and 510 are formed in different metal layers, the inductors 220, 230, and 510 may be electrically coupled by vias (not shown). In some implementations, two of the inductors 220, 230, and 510 may be formed from the same metal layer while the remaining inductor is formed from a different metal layer.

Each of the inductors 220, 230, and 510 may have any one of various shapes including a loop shape (e.g., rectangular loop), a spiral shape, a U shape, or another shape. Each of the inductors 220, 230, and 510 may have a single turn or multiple turns.

In the example shown in FIG. 9, the second inductor 230 is located within an inner loop of the first inductor 220 to facilitate inductive coupling between the inductors 220 and 230, which provides the mutual coupling M discussed above. For example, the coupling factor Km between the inductors 220 and 230 may be between 0.3 and 0.7, but is not limited to this example. FIG. 9 shows an example of the direction of current flow in the first inductor 220 and the second inductor 230 for the case where current enters the first terminal 212. As shown in FIG. 9, the direction of current flow is the same (e.g., clockwise) in the first inductor 220 and the second inductor 230 in this example.

In the example shown in FIG. 9, the boost inductor 510 is placed diagonally from the first and second inductors 220 and 230 to significantly reduce inductive coupling between the boost inductor 510 and each of the inductors 220 and 230. This helps ensure a very low coupling factor between the boost inductor 510 and each of the inductors 220 and 230. For example, the coupling factor between the boost inductor 510 and each of the inductors 220 and 230 may be less than 0.1. However, it is to be appreciated that the present disclosure is not limited to this example, and that other techniques may be employed to achieve a very low coupling factor between the boost inductor 510 and each of the inductors 220 and 230.

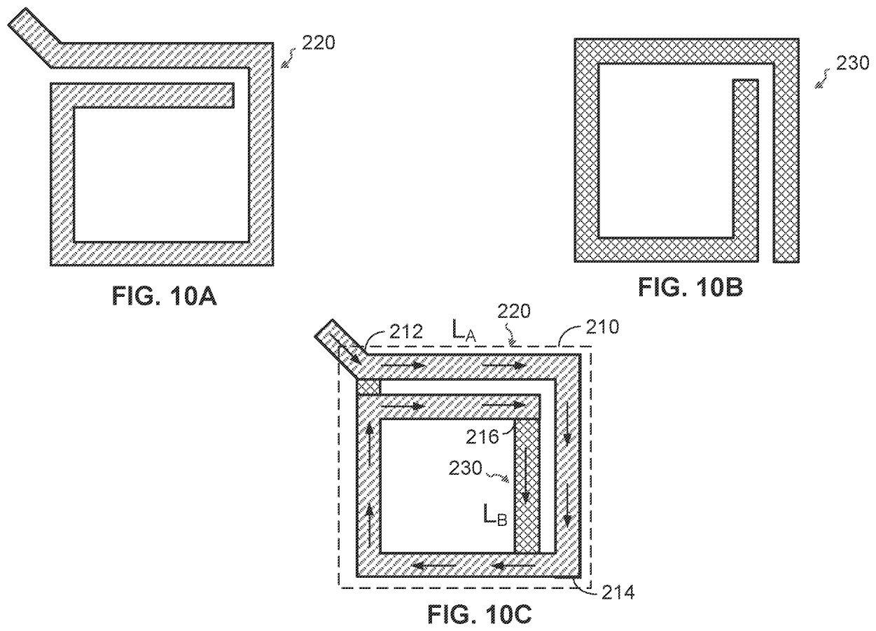

In certain aspects, mutual coupling between the first inductor 220 and the second inductor 230 may be achieved by stacking the first inductor 220 on top of the second inductor 230, or vice versa. In this regard, FIG. 10A shows a top view of the first inductor 220 and FIG. 10B shows a top view of the second inductor 230. In this example, the first inductor 220 is formed from a first metal layer (e.g., using lithographic and etching processes) and the second inductor 230 is formed from a second metal layer (e.g., using lithographic and etching processes). The second metal layer may be below or above the first metal layer.

FIG. 10C shows an example in which the first inductor 220 shown in FIG. 10A is placed over the second inductor 230 shown in FIG. 10B. In this example, the overlap between the first inductor 220 and the second inductor 230 facilitates inductive coupling between the inductors 220 and 230, which provides the mutually coupling M discussed above. In this example, the first inductor 220 and the second inductor 230 may be electrically coupled by a via (not shown) between the first metal layer and the second metal layer. Also, the boost inductor 510 (shown in FIG. 9) may be placed diagonally from the first and second inductors 220 and 230 to achieve a very low coupling factor (e.g., less than 0.1) between the boost inductor 510 and each of the inductors 220 and 230.

Implementation examples are described in the following numbered clauses:

1. A chip, comprising:
a pad;
a T-coil circuit having a first terminal, a second terminal, and a third terminal, wherein the first terminal of the T-coil circuit is coupled to the pad, and the T-coil circuit comprises:
   a first inductor coupled between the first terminal and the third terminal; and
   a second inductor coupled between the third terminal and the second terminal, wherein the first inductor and the second inductor are inductively coupled to one another;
a receive circuit coupled to the second terminal of the T-coil circuit;
a termination resistor;
a third inductor coupled between the second terminal of the T-coil circuit and the termination resistor; and
a bridge capacitor coupled between the pad and the termination resistor.

2. The chip of clause 1, further comprising an electrostatic discharge (ESD) protection circuit coupled to the third terminal of the T-coil circuit.

3. The chip of clause 2, wherein the ESD protection circuit includes a diode coupled between the third terminal of the T-coil circuit and a bus.

4. The chip of clause 2, wherein the ESD protection circuit includes a first diode coupled between the third terminal of the T-coil circuit and a first bus, and a second diode coupled between a second bus and the third terminal of the T-coil circuit.

5. The chip of anyone one of clauses 1 to 4, wherein the receive circuit comprises an equalizer.

6. The chip of anyone one of clauses 1 to 4, wherein the receive circuit comprises an amplifier.

7. The chip of anyone one of clauses 1 to 4, wherein the receive circuit comprises a slicer.

8. The chip of anyone one of clauses 1 to 7, wherein the second inductor is located within an inner loop of the first inductor.

9. The chip of clause 8, wherein the third inductor is located diagonally from the first inductor and the second inductor.

10. The chip of anyone one of clauses 1 to 7, wherein the first inductor overlaps the second inductor.

11. The chip of anyone one of clauses 1 to 10, wherein a coupling factor between the first inductor and the second inductor is between 0.3 and 0.7.

12. The chip of clause 11, wherein a coupling factor between the third inductor and each of the first inductor and the second inductor is less than 0.1.

13. A chip, comprising:
a pad;
an electrostatic discharge (ESD) protection circuit;
a receive circuit;
a first inductor coupled between the pad and the ESD protection circuit;
a second inductor coupled between the ESD protection circuit and the receive circuit, wherein the first inductor and the second inductor are inductively coupled to one another;
a termination resistor;
a third inductor coupled between the receive circuit and the termination resistor; and
a bridge capacitor coupled between the pad and the termination resistor.

14. The chip of clause 13, wherein the ESD protection circuit includes a diode coupled between the first inductor and a bus.

15. The chip of clause 13, wherein the ESD protection circuit includes a first diode coupled between the first inductor and a first bus, and a second diode coupled between a second bus and the first inductor.

16. The chip of any one of clauses 13 to 15, wherein the second inductor is located within an inner loop of the first inductor.

17. The chip of clause 16, wherein the third inductor is located diagonally from the first inductor and the second inductor.

18. The chip of any one of clauses 13 to 15, wherein the first inductor overlaps the second inductor.

19. The chip of any one of clauses 13 to 18, wherein a coupling factor between the first inductor and the second inductor is between 0.3 and 0.7.

20. The chip of clause 19, wherein a coupling factor between the third inductor and each of the first inductor and the second inductor is less than 0.1.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures unless otherwise specified. It is also to be appreciated that an output may include multiple parallel outputs, and that an input may include multiple parallel inputs.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a pad;
a T-coil circuit having a first terminal, a second terminal, and a third terminal, wherein the first terminal of the T-coil circuit is coupled to the pad, and the T-coil circuit comprises:
a first inductor coupled between the first terminal and the third terminal; and
a second inductor coupled between the third terminal and the second terminal, wherein the first inductor and the second inductor are inductively coupled to one another;
a receive circuit coupled to the second terminal of the T-coil circuit;
a termination resistor;
a third inductor coupled between the second terminal of the T-coil circuit and the termination resistor; and
a bridge capacitor coupled between the pad and the termination resistor.

2. The chip of claim 1, further comprising an electrostatic discharge (ESD) protection circuit coupled to the third terminal of the T-coil circuit.

3. The chip of claim 2, wherein the ESD protection circuit includes a diode coupled between the third terminal of the T-coil circuit and a bus.

4. The chip of claim 2, wherein the ESD protection circuit includes a first diode coupled between the third terminal of the T-coil circuit and a first bus, and a second diode coupled between a second bus and the third terminal of the T-coil circuit.

5. The chip of claim 1, wherein the receive circuit comprises an equalizer.

6. The chip of claim 1, wherein the receive circuit comprises an amplifier.

7. The chip of claim 1, wherein the receive circuit comprises a slicer.

8. The chip of claim 1, wherein the second inductor is located within an inner loop of the first inductor.

9. The chip of claim 8, wherein the third inductor is located diagonally from the first inductor and the second inductor.

10. The chip of claim 1, wherein the first inductor overlaps the second inductor.

11. The chip of claim 1, wherein a coupling factor between the first inductor and the second inductor is between 0.3 and 0.7.

12. The chip of claim 11, wherein a coupling factor between the third inductor and each of the first inductor and the second inductor is less than 0.1.

13. A chip, comprising:
a pad;
an electrostatic discharge (ESD) protection circuit;
a receive circuit;
a first inductor coupled between the pad and the ESD protection circuit;
a second inductor coupled between the ESD protection circuit and the receive circuit, wherein the first inductor and the second inductor are inductively coupled to one another;
a termination resistor;
a third inductor coupled between the receive circuit and the termination resistor; and
a bridge capacitor coupled between the pad and the termination resistor.

14. The chip of claim 13, wherein the ESD protection circuit includes a diode coupled between the first inductor and a bus.

15. The chip of claim 13, wherein the ESD protection circuit includes a first diode coupled between the first inductor and a first bus, and a second diode coupled between a second bus and the first inductor.

16. The chip of claim 13, wherein the second inductor is located within an inner loop of the first inductor.

17. The chip of claim 16, wherein the third inductor is located diagonally from the first inductor and the second inductor.

18. The chip of claim 13, wherein the first inductor overlaps the second inductor.

19. The chip of claim 13, wherein a coupling factor between the first inductor and the second inductor is between 0.3 and 0.7.

20. The chip of claim 19, wherein a coupling factor between the third inductor and each of the first inductor and the second inductor is less than 0.1.
